(19) United States
(12) Patent Application Publication
(10) Pub. No.: US 2020/0192542 A1
(43) Pub. Date: Jun. 18, 2020

(54) DISPLAY DEVICE WITH INTEGRATED ANTENNA AND METHOD THEREOF

(71) Applicant: Novatek Microelectronics Corp., Hsinchu (TW)

(72) Inventors: Wei-Hsiu Chang, Taichung City (TW); Feng-Ting Pai, Hsinchu City (TW)

(73) Assignee: Novatek Microelectronics Corp., Hsinchu (TW)

(21) Appl. No.: 16/438,501

(22) Filed: Jun. 12, 2019

Related U.S. Application Data
(60) Provisional application No. 62/778,292, filed on Dec. 12, 2018.

(51) Int. Cl. G06F 3/041; H01L 27/12; G09G 3/36; G09G 3/3225; H01Q 1/38; H01Q 1/24; H04W 52/02

(52) U.S. Cl. CPC G06F 3/04162; H01L 27/1255; G09G 3/3648; G02F 1/1368; H01Q 1/38; H01Q 1/24; H04W 52/0229; G09G 3/3225

(57) ABSTRACT

A method and a display device with an integrated antenna that are capable of efficiently utilizing internal space of the display device as well as avoiding interferences are introduced. The display device includes a display panel, the antenna being integrated in the inactive display area of the display panel, and a display driver. The display panel includes an active display area and an inactive display area, in which the inactive display area is disposed outside the active display area. The display driver is coupled to the display panel and the antenna, and is configured to control the antenna and the display panel in a time-sharing manner.

### CROSS-REFERENCE TO RELATED APPLICATION

This application claims the priority benefit of U.S. provisional application Ser. No. 62/778,292, filed on Dec. 12, 2018. The entirety of the above-mentioned patent application is hereby incorporated by reference herein and made a part of this specification.

### BACKGROUND

### Technical Field

The disclosure generally relates to a display device, and more particularly relates to a method and a display device with an integrated antenna that are capable of efficiently utilizing internal space of the display device and avoiding interferences among antenna operations, touching operations and displaying operations.

### Description of Related Art

Generally, an antenna and an antenna controller are placed in a display device to enable a wireless communication capability for the display device. However, the antenna and the antenna controller may occupy a large internal area of the display device. In addition, operations of the antenna and the antenna controller may cause interferences to operations of the display panel in the display device, and vice versa. As a result, performance of the display device is degraded because of the interferences.

As demand for miniaturization and better performance of the display device has grown recently, there has grown a need for a more creative technique to efficiently integrating antenna to a display panel, utilizing the internal space of the display device and avoiding the interferences to the display and touch drivings of the display device.

Nothing herein should be construed as an admission of knowledge in the prior art of any portion of the present disclosure.

### SUMMARY

A method and a display device with an integrated antenna that are capable of efficiently utilizing internal space of the display device and avoiding interferences among antenna operations, touching operations and displaying operations are introduced.

In an embodiment of the disclosure, the display device includes a display panel, an antenna being integrated in an inactive display area of the display panel, and a display driver. The display panel includes an active display area and the inactive display area, in which the inactive display area is disposed outside the active display area. The display driver is coupled to the display panel and the antenna, and is configured to control the antenna and the display panel in a time-sharing manner.

In an embodiment of the disclosure, a method that is adapted to a display device having an integrated antenna includes steps of broadcasting a polling signal using the integrated antenna during a polling interval; listening for a response signal from another device during a listening interval; and connecting and communicating with the other device in response to receiving the response signal from the other device. The listening interval is longer than the polling signal, and the polling interval is within a blanking interval of the display device.

To make the disclosure more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic diagram illustrating a display device according to an embodiment of the disclosure.

FIG. 2 is a schematic diagram illustrating a display driver of a display device according to an embodiment of the disclosure.

FIG. 3A, FIG. 3B, FIG. 3C and FIG. 3D illustrate locations of an integrated antenna in a liquid crystal display (LCD) panel according to some embodiments of the disclosure.

FIG. 4A, FIG. 4B and FIG. 4C illustrate locations of an integrated antenna in an organic light-emitting diode (OLED) display panel according to some embodiments of the disclosure.

FIG. 5 illustrates an antenna signal in a discovery mode of a display device with an integrated antenna according to an embodiment of the disclosure.

FIG. 6 illustrates different signals of a display device with an integrated antenna according to an embodiment of the disclosure.

FIG. 7 is a flowchart diagram illustrating a method adapted to a display device according to an embodiment of the disclosure.

### DESCRIPTION OF THE EMBODIMENTS

It is to be understood that other embodiments may be utilized and structural changes may be made without departing from the scope of the present disclosure. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted,” and variations thereof herein are used broadly and encompass direct and indirect connections, couplings, and mountings.

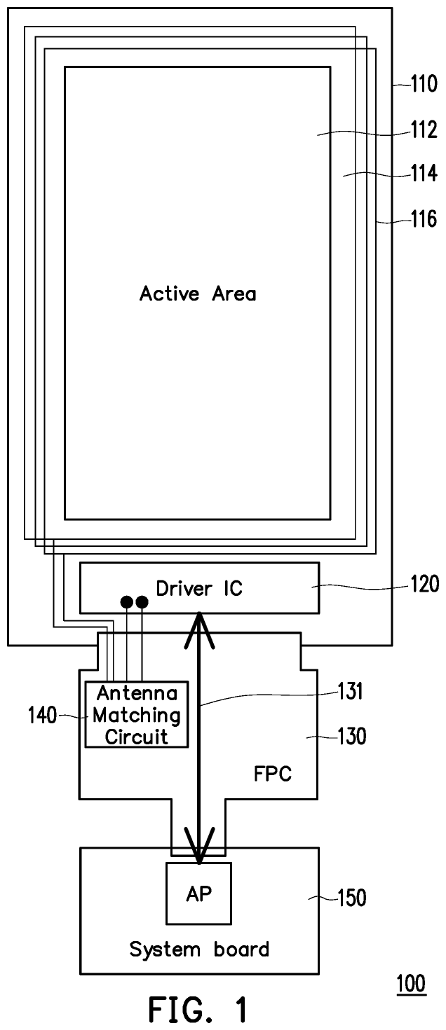

Referring to FIG. 1, a schematic diagram of a display device 100 according to an embodiment of the disclosure is illustrated. The display device 100 may include a display panel 110, an antenna 116 being integrated in the display panel 110 and a display driver 120. The display panel 110 includes an active area 112 and an inactive area 114, in which the inactive area 114 is located outside the active area 112. In some embodiments of the disclosure, the inactive area 114 are located in outer periphery (or surround space) of the active area 112. For example, an outer boundary of the active area 112 may be an inner boundary of the inactive area 114. In some embodiments, the active area 112 may include a plurality of display elements (e.g. pixels) that are controlled by the display driver 120 to display image data. The active area 112 may further include sensing patterns that are configured to sense a value from the active area 112. For example, the sensing patterns may be configured to sense a touch or a gesture of user on a surface of the active area 112. The display panel 110 could be a liquid crystal display (LCD) panel, an organic light-emitting diode (OLED) display panel, or any other type of display panel.

In some embodiments, the antenna 116 is integrated in the inactive area 114 of the display panel 110, and is configured to support wireless communication capability at one or more frequencies according to different wireless standards. For example, the antenna 116 may support near field communication (NFC), Bluetooth, WiFi, Zigbee, and any other wireless communication standard. In some embodiments, the antenna 116 may also support wireless power transfer (WPT) for the display device 100. In an embodiment of the disclosure, the antenna 116 may be a coil antenna pattern that is located in the inactive area 114 of the display panel 110. However, any other type of antennal falls within the scope of the disclosure, and a size, shape, location and dimension of the antenna 116 may be determined according to designed needs.

In some embodiments of the disclosure, the display driver 120 is electrically coupled to the antenna 116 and the display panel 110 and is configured to control both of the displaying and touching operations using the display panel 110 and antenna operations using the antenna 116. In other words, display driver 120 also includes functions of an antenna controller. In this way, a separated antenna controller is not necessary, and the occupied space for the antenna 116 and the antenna-related components are reduced. The display driver 120 may be disposed in the inactive area 114 of the display panel 110 or any other location in the display device 100.

In some embodiments, the display driver 120 is configured to control the display panel 110 and the antenna 116 in a time sharing manner. In an example, the display driver 120 may control the display panel 110 during a displaying interval and control the antenna 116 during a blank interval, where the displaying interval is not overlapped with the blank interval. During the blank interval, the display content on the display panel is held without an update, thus, the interferences between the antenna operations of the antenna 116 and the displaying operations of the display panel 110 are avoided.

In another example, the display panel 110 supports displaying operations and touching operations, and the display driver 120 may control the display panel 110 during a displaying and touching interval and control the antenna 116 during a blank interval, where the displaying and touching interval is not overlapped with the blank interval. During the displaying and touching interval, at least one of touching operations and displaying operations are performed to the display panel 116. During the blank interval, the display content on the display panel is held without an update and no touch sensing operation is performed. Since display driver 120 control operations of the display panel 110 and operations of the antenna 116 in non-overlapping intervals, interferences between antenna operations of the antenna 116 and operations of the display panel 110 (e.g., displaying operations and touching operations) are avoided.

In some embodiments, the display device 100 may be designed using chip-on-glass (COG) technology, in which integrated circuits (ICs) such as display driver (also known as driver IC) could be mounted directly on the display glass of the display panel. However, the disclosure is not limited to any particular design and manufacturing technology. For example, the display device 100 may be designed using chip-on-film (COF) technology, chip-on-plastic (COP) technology and any other suitable technologies.

In some embodiments, when the antenna is in a stand-by mode or a sleep mode or a low-power mode or a power-off mode, the display driver 120 may set a pre-determined voltage level to the antenna 116 to further prevent the interferences between operations of the antenna and operations (e.g., displaying operations and touching operations) of the display panel 110.

In some embodiments of the disclosure, the display device 100 further includes a flexible printed circuit 130 and a system board 150. The system board 150 may include a processor, a memory and a plurality of electronic circuits, and is configured to cooperate with the display driver 120 to control the display panel 110, antenna 116 and other circuits. The memory may store instructions of an application AP that are executable by the processor to perform specific tasks. The flexible printed circuit 130 functions as a cable connector that electrically couples the display driver 120 to the system board 150 to transmits signals between the display driver 120 to the system board 150.

In an embodiment of the disclosure, the display device 100 further includes an antenna matching circuit 140 that is electrically coupled between the antenna 116 and the display driver 120. The antenna matching circuit 140 may be disposed on the flexible printed circuit 130, or anywhere in the display device 100. The antenna matching circuit 140 is configured to perform an impedance matching between the antenna 116 and the display driver 120, thereby preventing the reflection of signals transmitted between the antenna 116 and the display driver 120.

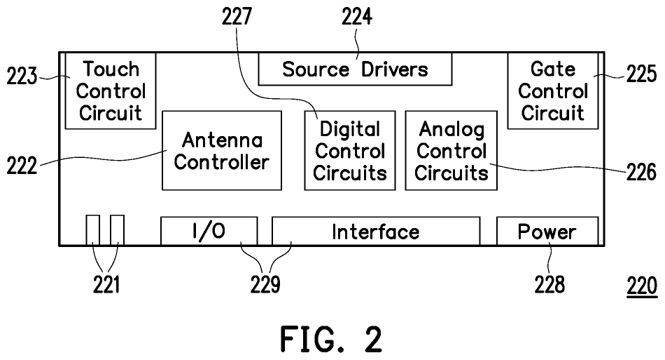

Referring to FIG. 2, a display driver 220 according to an embodiment of the disclosure is illustrated. The display driver 220 includes an antenna interface 221, an antenna control 222, a touch control circuit 223, a source driver 224, gate control circuit 225, analog control circuits 226, digital control circuits 227, a power 228 and interface and input/output ends 229. The antenna controller 222 is integrated in the display driver 220 and is configured to control operations of the antenna. The antenna control 222 may control and communicate with the antenna through the antenna interface 221 which is coupled to the antenna directly or indirectly through an antenna impedance matching circuit. The touch control circuit 223, the source driver 224, the gate control circuit 225, the analog control circuits 226, the digital control circuits 227, the power 228 and the interfaces 229 of the display driver 220 are configured to control the display panel, and to communicate with the other electronic components. One of skilled in the art would be clear about the structure and operation of the touch control circuit 223, the source driver 224, the gate control circuit 225, the analog control circuits 226, the digital control circuits 227, the power 228 and the interfaces 229, thus the detailed description regarding the above-mentioned components are omitted hereafter.

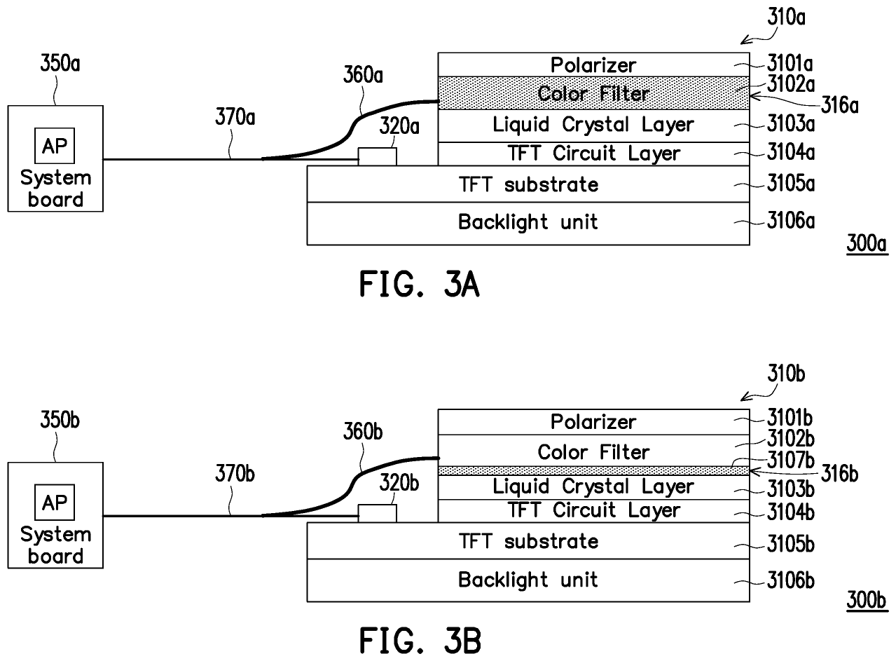

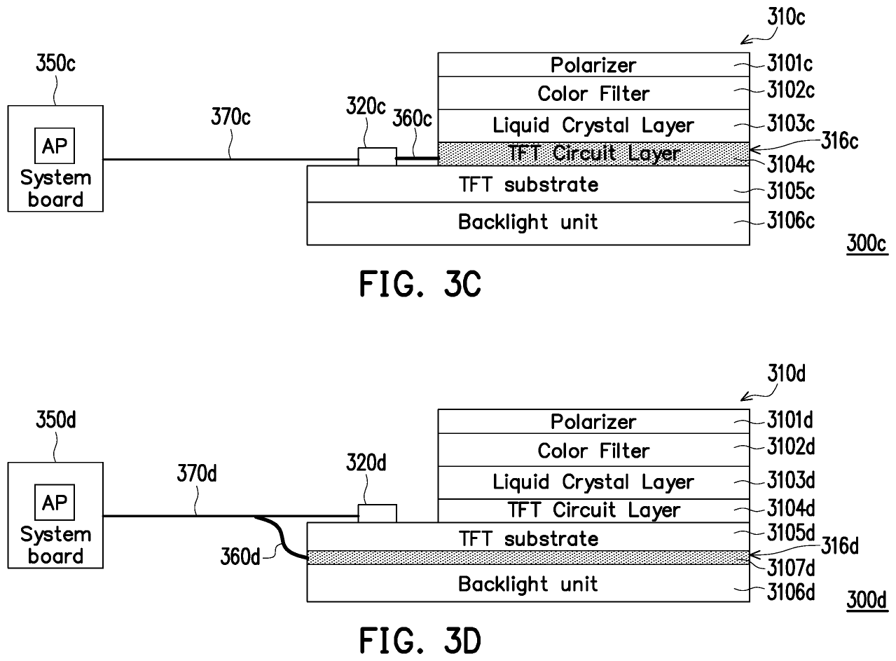

Referring to FIG. 3A to 3D, locations of an integrated antenna in a liquid crystal display (LCD) panel according to some embodiments of the disclosure are illustrated. From the front side to the rear side of the LCD panel, the LCD panel may include a polarizer, a color filter, a liquid crystal layer, a thin-film transistor (TFT) circuit layer, a TFT substrate and a backlight unit.

Referring to FIG. 3A, a display device 300a that includes a LCD panel 310a, a display driver 320a, a flexible printed circuit 370a and a system board 350a is illustrated. The LCD panel 310a includes a polarizer 3101a, a color filter 3102a, a liquid crystal layer 3103a, a thin-film transistor (TFT) circuit layer 3104a, a TFT substrate 3104a and a backlight unit 3106a. An antenna 316a is integrated in the color filter 3102a of the LCD panel 310a. In an embodiment of the disclosure, the antenna 316a is disposed in an inactive area of the LCD panel 310a, and is in the same layer of the color filter 3102a of the LCD panel 310a.

In FIG. 3A, since the display driver 320a and the antenna 316a are located in different layers of the display panel 310a, a flexible printed circuit 360a is used to electrically couple the display driver 320a to the antenna 316a. More specifically, the display driver 320a is located in the TFT circuit layer 3104a which is different from the layer of the color filter 3102a, thus the flexible printed circuit 306a is used to electrically couple the antenna 316a to the display driver 320a. In some embodiments, the antenna 316a may couple to the system board 350a through the flexible printed circuits 360a and 370a and the display driver 320a.

Referring to FIG. 3B, a display device 300b that includes a LCD panel 310b, a display driver 320b, a flexible printed circuit 370b and a system board 350b is illustrated. The LCD panel 310b includes a polarizer 3101b, a color filter 3102b, a liquid crystal layer 3103b, a TFT circuit layer 3104b, a TFT substrate 3104b and a backlight unit 3106b. An antenna 316b is integrated in a layer 3107b located between the color filter 3102b and the liquid crystal layer 3103b. In an embodiment, the antenna 316b may be disposed in an inactive area of the display panel 310b, and is in the layer 3107b which is sandwiched between the color filter 3102b and the liquid crystal layer 3103b of the display panel 310b.

In FIG. 3B, the display driver 320b is located in the TFT circuit layer 3104b which is different from the layer 3107b of the antenna 316b, thus a flexible printed circuit 306b is used to electrically couple the antenna 316b to the display driver 320b. In some embodiments, the antenna 316b may couple to the system board 350b through the flexible printed circuits 360b and 370b and the display driver 320b.

Referring to FIG. 3C, a display device 300c that includes a LCD panel 310c, a display driver 320c, a flexible printed circuit 370c and a system board 350c is illustrated. The LCD panel 310c includes a polarizer 3101c, a color filter 3102c, a liquid crystal layer 3103c, a TFT circuit layer 3104c, a TFT substrate 3104c and a backlight unit 3106c. An antenna 316c is integrated in the TFT circuit layer 3104c of the LCD panel 310c. In an embodiment of the disclosure, the antenna 316c is disposed in an inactive area of the LCD panel 310c, and is in the same layer of the TFT circuit layer 3104c of the LCD panel 310c.

In FIG. 3C, the antenna 316c and the display driver 320c are located in a same layer of the display panel 310c, the antenna 316c may electrically couple to the display driver 320c through electrical connector 360c. The antenna 316c may couple to the system board 350c through the electrical connector 360c, the flexible printed circuit 370c and the display driver 320c.

Referring to FIG. 3D, a display device 300d that includes a LCD panel 310d, a display driver 320d, a flexible printed circuit 370d and a system board 350d is illustrated. The LCD panel 310d includes a polarizer 3101d, a color filter 3102d, a liquid crystal layer 3103d, a TFT circuit layer 3104d, a TFT substrate 3104d and a backlight unit 3106d. An antenna 316d is integrated in a layer 3107d that is located between the TFT substrate 3105d and the backlight unit 3106d. In an embodiment, the antenna 316d may be disposed in an inactive area of the display panel 310d, and is in the layer 3107d which is sandwiched between the TFT substrate 3105d and the backlight unit 3106d.

In FIG. 3D, since the display driver 320d is located in the TFT circuit layer 3104d which is different from the layer 3107d of the antenna 316d, a flexible printed circuit 306bd is used to electrically couple the antenna 316d to the display driver 320d. In some embodiments, the antenna 316d may couple to the system board 350d through the flexible printed circuits 360d and 370d and the display driver 320d.

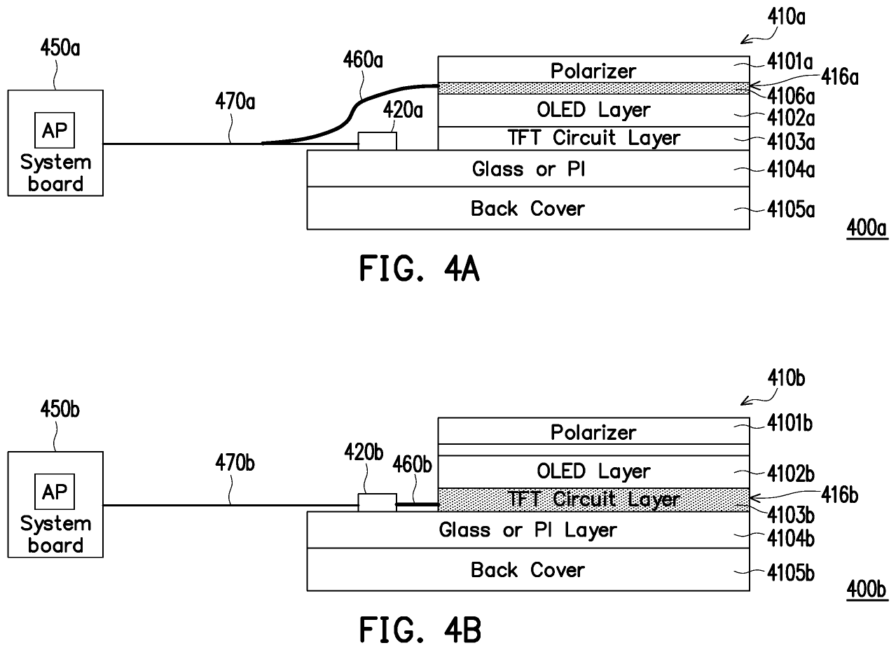

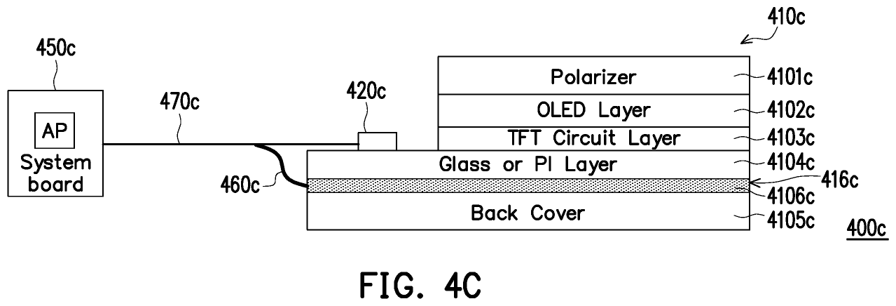

Referring to FIG. 4A to FIG. 4C, locations of an integrated antenna in an organic light-emitting diode (OLED) display panel according to some embodiments of the disclosure is illustrated. From the front side to the rear side of the OLED display panel, the OLED display panel may include a polarizer, an OLED layer, a TFT circuit layer, a glass layer and a back cover.

Referring to FIG. 4A, a display device 400a that includes an OLED display panel 410a, a display driver 420a, a flexible printed circuit 470a and a system board 450a is illustrated. The OLED display panel 410a includes a polarizer 4101a, an OLED layer 4102a, a TFT circuit layer 4103a, a glass layer 4104a and a back cover 4105a. An antenna 416a is integrated in a layer 4106a which is located between the polarizer 4101a and the OLED layer 4102a. In an embodiment of the disclosure, the antenna 416a is disposed in an inactive area of the OLED display panel 410a, and is in the layer 4106a which is sandwiched between the polarizer 4101a and the OLED layer 4102a.

In FIG. 4A, the display driver 420a is located in the TFT circuit layer 4103a which is different from the layer 4106a of the antenna 416a, thus a flexible printed circuit 460a is used to electrically couple the antenna 416a to the display driver 420a. In some embodiments, the antenna 416a may couple to the system board 450a through the flexible printed circuits 460a and 470a and the display driver 420a.

Referring to FIG. 4B, a display device 400b that includes an OLED display panel 410b, a display driver 420b, a flexible printed circuit 470b and a system board 450b is illustrated. The OLED display panel 410b includes a polarizer 4101b, an OLED layer 4102b, a TFT circuit layer 4103b, a glass layer 4104b and a back cover 4105b. An antenna 416b is integrated in the TFT circuit layer 4103b. In an embodiment of the disclosure, the antenna 416b is disposed in an inactive area of the OLED display panel 410b, and is in the TFT circuit layer 4103b of the OLED display panel 410b.

In FIG. 4B, the display driver 420b and the antenna 416b are located in the same TFT circuit layer 4103b, thus the antenna 416b may electrically couple to the display driver 420a through electrical connector 460b. The antenna 416b may couple to the system board 450b through the electrical connector 460b, the flexible printed circuit 470b and the display driver 420a.

Referring to FIG. 4C, a display device 400c that includes an OLED display panel 410c, a display driver 420c, a flexible printed circuit 470c and a system board 450c is illustrated. The OLED display panel 410c includes a polarizer 4101c, an OLED layer 4102c, a TFT circuit layer 4103c, a glass layer 4104c and a back cover 4105c. An antenna 416c is integrated in a layer 4106c which is located between the glass layer 4104c and the back cover 4105c of the OLED display panel 410c. In an embodiment of the disclosure, the antenna 416c is disposed in an inactive area of the OLED display panel 410c, and is in the layer 4106c which is sandwiched between the glass layer 4104c and the back cover 4105c.

In FIG. 4C, the display driver 420c is located in the TFT circuit layer 4103c which is different from the layer 4106c of the antenna 416c, thus a flexible printed circuit 460c is used to electrically couple the antenna 416c to the display driver 420c. In some embodiments, the antenna 416ac may couple to the system board 450c through the flexible printed circuits 460c and 470c and the display driver 420c.

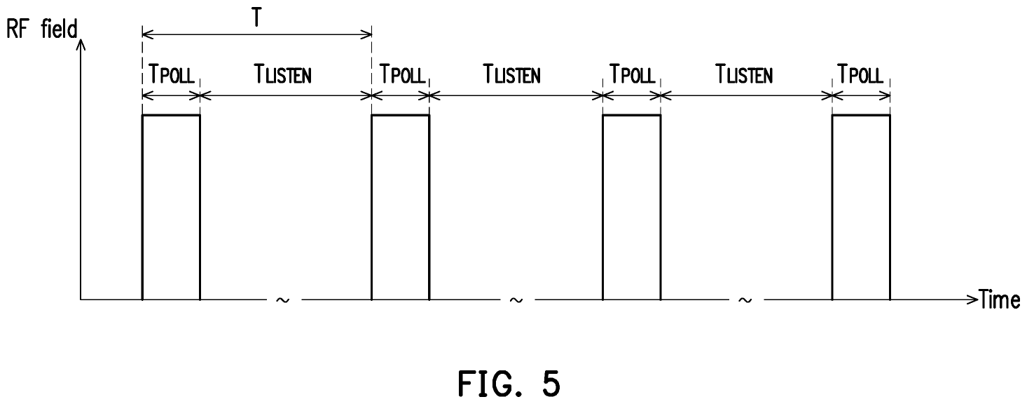

Referring to FIG. 5, an antenna signal in a discovery mode of a display device having an integrated antenna according to an embodiment of the invention is illustrated. The discover mode is configured to discover other device to be connected to the display device by periodically generate radio frequency (RF) field and listen to a response signal. In an embodiment, the discovery mode is activated when the display device is power on.

In the discovery mode, there are a number of periodic time intervals T, where each of the periodic time intervals T includes a polling interval T_{POLL} and a listening interval T_{LISTEN}. RF field is generated and broadcasted to environment surrounding the display device in the polling interval T_{POLL}. The display device stops generating the RF field and listens to a response signal from other device in the listening interval T_{LISTEN}. In some embodiments of the disclosure, the listening interval T_{LISTEN} is longer than the polling interval T_{POLL}, but the disclosure is not limited thereto.

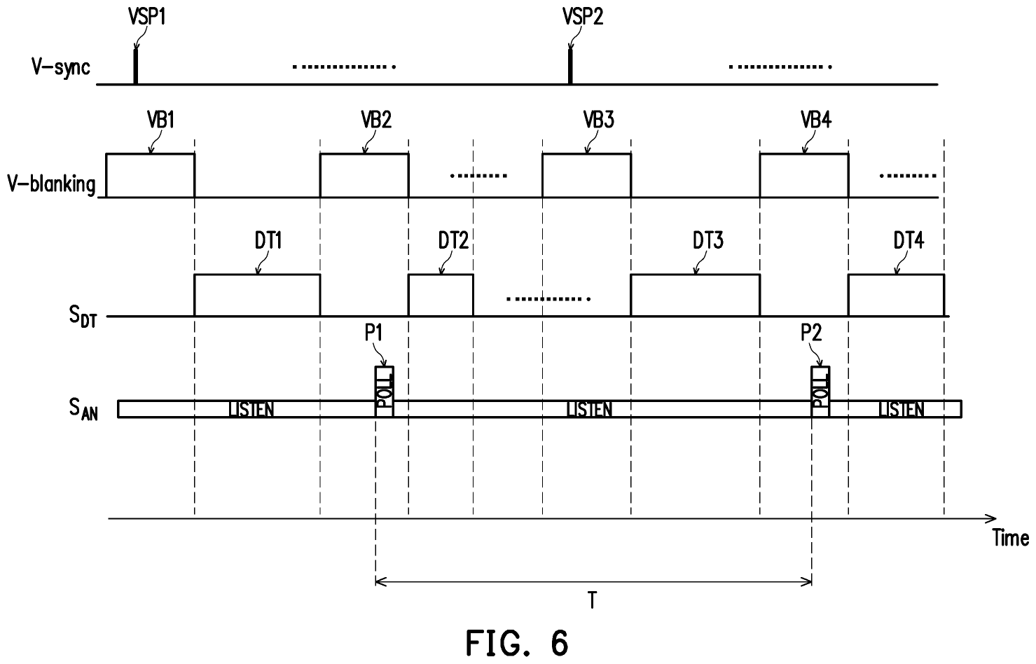

Referring to FIG. 6, different signals of a display device with integrated antenna and timings of these signals according to an embodiment of the disclosure is illustrated. The signals include a vertical synchronizing signal Vsync, display and touch signals S_{DT}, and an antenna signal S_{AN}, in which the display and touch signals S_{DT} are used for the display panel of the display device and the antenna signal S_{AN} are used for the integrated antenna of the display device.

The vertical synchronizing signal Vsync may include a plurality of vertical synchronizing pulses that occur within vertical blanking intervals of the display device. For the example shown in FIG. 6, the vertical synchronizing pulses VSB1 and VSB2 occur within the vertical blanking intervals VB1 and VB3, respectively. The display and touch signals S_{DT} may be used to display image data on the display panel and sense a touch or a gesture being performed on the display panel. The display and touch signals S_{DT} occur during display and touch intervals DT1 to DT4 that are not overlapped with any of the vertical blanking intervals VB1 to VB4 of the display device. In other words, in vertical blanking intervals VB1 to VB4, no display and touch signal is applied to the display panel of the display device, and thus, display content on the display panel is held without an update.

The antenna signal S_{AN} may be used for the antenna in different modes for discovering, pairing, communicating with other devices and performing other related functions. In FIG. 6, the antenna signal S_{AN} which is used in a discovery mode includes polling pulses P1 and P2 that occur within vertical blanking intervals VB2 to VB4 of the display device. The polling pulses P1 and P2 is used for RF field generation, where the RF field is broadcasted to surrounding environment during a polling interval so as to detect or discover other devices to be connected. The display panel stops generating the RF field and listens to a response signal from other device during a listening interval. The discovery mode may include a plurality of periodic time intervals, where each of the periodic time intervals includes a polling interval and a listening interval. The lengths of the polling interval and the listening interval are set according to designed needs.

Since the polling intervals P1 and P2 are within the vertical blanking interval VB2 and VB4, the generation of the RF field does not interfere the display and touch signal S_{DT} for controlling the display panel. In other words, the display driver may control both of the antenna using the antenna signal S_{AN} and the display panel using the display and touch signals S_{DT} without interference each other.

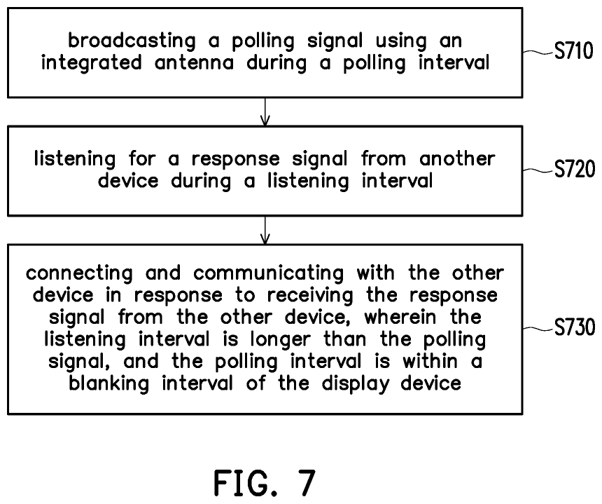

Referring to FIG. 7, a method adapted to a display device with an integrated antenna according to an embodiment of the disclosure is illustrated. In step S710, a polling signal is broadcasted using the integrated antenna during a polling interval. The polling signal may be a RF field which is broadcasted by the integrated antenna. In step S720, the display device with the integrated antenna listens for a response signal from another device during a listening interval. In steps S730, the display device with the integrated antenna connects and communicates with the other device in response to receiving the response signal from the other device. The listening interval is longer than the polling signal, and the polling interval is within a blanking interval of the display device.

From the above embodiments, an antenna is integrated in an inactive display area of a display panel of a display device, and an antenna controller is integrated in a display driver of the display device. In other words, the display driver is configured to control both of the display panel of the display device and the integrated antenna. As such, an interference between the display panel and the antenna is prevented and the internal space of the display device is efficiently utilized. In addition, the antenna is used to broadcast polling signal (e.g., RF field) during a blank interval of the display device, thus preventing the interference of antenna operations to the display panel operations (e.g., touching operations and/or displaying operations), and vice versa.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A display device, comprising:
a display panel, comprising an active display area and an inactive display area, wherein the inactive display area is disposed outside the active display area;
an antenna, integrated in the inactive display area of the display panel, and
a display driver, coupled to the display panel and the antenna, and configured to control the antenna and the display panel in a time-sharing manner.

2. The display device of claim 1, wherein the display driver is further configured to control the antenna during a blanking interval, wherein the blanking interval includes a time interval when display content on the display panel is held without an update.

3. The display device of claim 1, wherein the display driver is further configured to control the display panel during a displaying and touching interval, wherein the displaying and touching interval is non-overlap with the blanking interval.

4. The display device of claim 1, wherein the display driver is further configured to set a pre-determined voltage level to the antenna when the antenna is in a stand-by mode or a sleep mode or a low-power mode or a power-off mode.

5. The display device of claim 1, wherein the display driver comprises:
an antenna interface, configured to couple the display driver to the antenna; and
an antenna controller, configured to control the antenna through the antenna interface.

6. The display device of claim 5, further comprising:
an antenna matching circuit, coupled between the antenna and the antenna interface of the display driver, and configured to perform an impedance matching processing to match an impedance of the antenna and an impedance of the display driver.

7. The display device of claim 1, wherein the display panel is a liquid crystal display panel having a color filter layer, and the antenna is integrated in the color filter layer.

8. The display device of claim 1, wherein the display panel is a liquid crystal display panel having a color filter layer and a liquid crystal layer, and the antenna is integrated between the color filter layer and the liquid crystal layer.

9. The display device of claim 1, wherein the display panel is a liquid crystal display panel having a thin-film transistor circuit layer, and the antenna is integrated in the thin-film transistor circuit layer.

10. The display device of claim 1, wherein the display panel is a liquid crystal display panel having a thin-film transistor substrate and a backlight unit, and the antenna is integrated between the thin-film transistor substrate and the backlight unit.

11. The display device of claim 1, wherein the display panel is an organic light-emitting diode panel having a polarizer and an organic light-emitting diode layer, and the antenna is integrated between the polarizer and the organic light-emitting diode layer.

12. The display device of claim 1, wherein the display panel is an organic light-emitting diode panel having a thin-film transistor circuit layer, and the antenna is integrated in the thin-film transistor circuit layer.

13. The display device of claim 1, wherein the display panel is an organic light-emitting diode panel having a glass layer and a back cover, and the antenna is integrated between the glass layer and the back cover.

14. A method adapted to a display device having an integrated antenna, comprising:
broadcasting a polling signal using the integrated antenna during a polling interval;
listening for a response signal from another device during a listening interval; and
connecting and communicating with the other device in response to receiving the response signal from the other device,
wherein the listening interval is longer than the polling signal, and the polling interval is within a blanking interval of the display device.

15. The method of claim 14, wherein the blanking interval includes a time interval when display content on the display panel is held without an update.

16. The method of claim 14, further comprising:
controlling a display panel of the display panel during a displaying and touching interval, wherein the displaying and touching interval is non-overlapped with the blanking interval.

17. The method of claim 14, further comprising:
setting a pre-determined voltage level to the integrated antenna when the integrated antenna is in a stand-by mode or a sleep mode or a low-power mode or a power-off mode of the integrated antenna.

18. The method of claim 14, wherein the polling interval and the listening interval form a periodic time interval of a discovery mode.
